(19) United States
(12) Patent Application Publication
(10) Pub. No.: US 2025/0006548 A1
(43) Pub. Date: Jan. 2, 2025

(54) FIELD EFFECT TRANSISTOR WITH DUAL LAYER ISOLATION STRUCTURE AND METHOD

(71) Applicant: Taiwan Semiconductor Manufacturing Co., Ltd., Hsinchu (TW)

(72) Inventors: Hsien-Chih HUANG, Hsinchu (TW); Guan-Lin CHEN, Hsinchu (TW); Chia-Hao CHANG, Hsinchu (TW); Shi Ning JU, Hsinchu (TW); Kuo-Cheng CHIANG, Hsinchu (TW); Chih-Hao WANG, Hsinchu (TW)

(21) Appl. No.: 18/499,908

(22) Filed: Nov. 1, 2023

Related U.S. Application Data
(60) Provisional application No. 63/510,736, filed on Jun. 28, 2023.

(51) Int. Cl. H01L 21/762; H01L 29/06; H01L 29/423; H01L 29/66

(52) U.S. Cl. CPC H01L 21/76229; H01L 29/0673; H01L 29/42392; H01L 29/66439; H01L 29/41775; H01L 29/78696

(57) ABSTRACT

An integrated circuit includes a transistor including a plurality of stacked channels. A first dielectric wall structure is positioned on a first lateral side of the stacked channels. A second dielectric wall structure is positioned on a second lateral side of the stacked channels. A dielectric home structure is positioned above the top channel. A gate electrode includes a vertical column extending vertically between the second dielectric wall structure and the stacked channels. The gate electrode includes finger portions extending laterally from the vertical column between the stacked channels.

### BACKGROUND

The semiconductor integrated circuit industry has experienced exponential growth. Technological advances in integrated circuit materials and design have produced generations of integrated circuits where each generation has smaller and more complex circuits than the previous generation. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1Y are perspective views of an integrated circuit at intermediate stages of processing, in accordance with some embodiments.

FIGS. 2A-2E are perspective views of an integrated circuit at intermediate stages of processing, in accordance with some embodiments.

FIGS. 3A-3E are perspective views of an integrated circuit at intermediate stages of processing, in accordance with some embodiments.

FIG. 4 is a flow diagram of a method for forming an integrated circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The present disclosure is generally related to semiconductor devices, and more particularly to field-effect transistors (FETs), such as planar FETs, three-dimensional fin FETs (FinFETs), or nanostructure devices. Examples of nanostructure devices include gate-all-around (GAA) devices, nanosheet FETs (NSFETs), nanowire FETs (NWFETs), and the like. In advanced technology nodes, a metal gate surrounds four sides of the nanostructures (e.g., nanosheets). Gate-drain capacitance (“Cgd”) is increased due to larger metal gate endcap and increased source/drain epitaxy size. In gate all around transistors, the gate metal between channel steps may directly face the source/drain contact metal and the source/drain regions. This can result in a large effective capacitance between the gate metal and the source/drain contact metals are source/drain regions.

Embodiments of the disclosure provide nanostructure transistors with reduced gate to source/drain capacitance. Embodiments of the present disclosure provide dielectric structures between adjacent channel stacks of adjacent transistors. The gate metals that are initially positioned between adjacent channel stacks is entirely replaced with dielectric material. This reduces the effect of area of gate metal that faces source/drain contact metals and source/drain regions. Furthermore, in some embodiments, a dielectric helmet structure may be placed directly above channel stacks to further reduce the height of the gate electrode and the area of gate metal that faces source/drain contact metals and source/drain regions. The result is that gate capacitances are greatly reduced. This further results in nanostructure transistors that can operate at higher frequencies, have superior electrical characteristics, and better overall performance. Furthermore, this can improve wafer yields and overall function of integrated circuits and electronic devices in which the integrated circuits are embedded.

The nanostructure transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructure transistor structure.

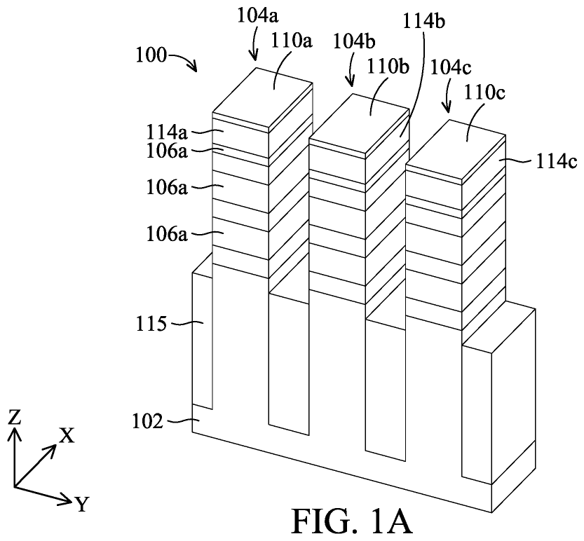

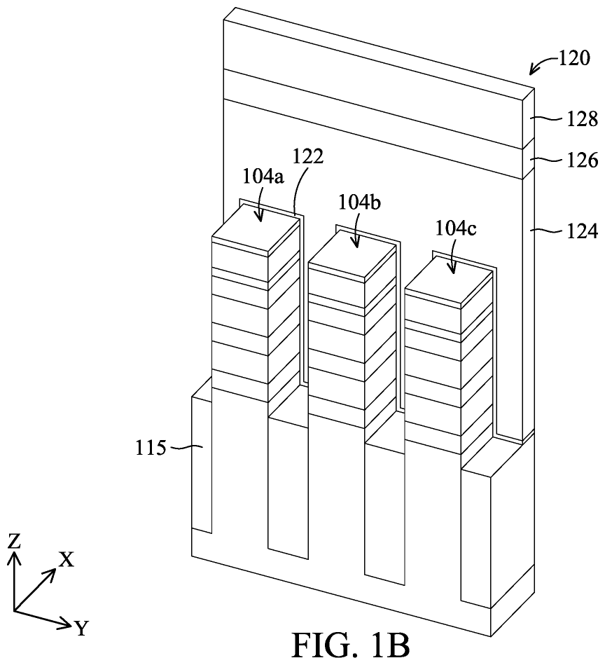

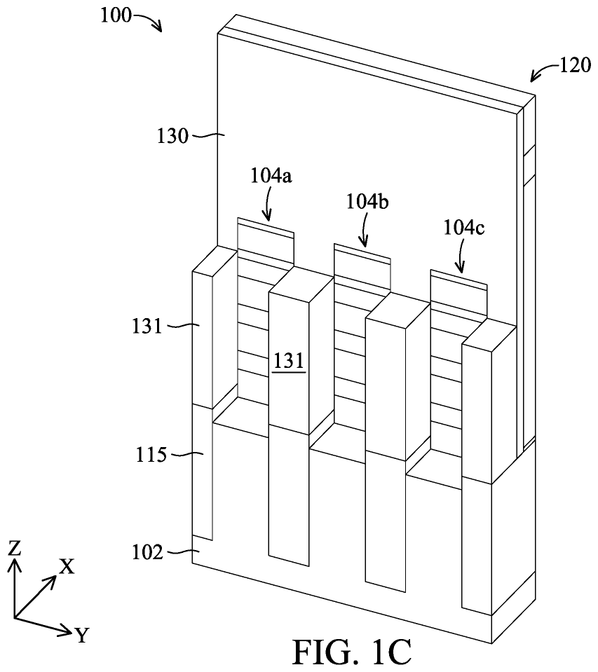

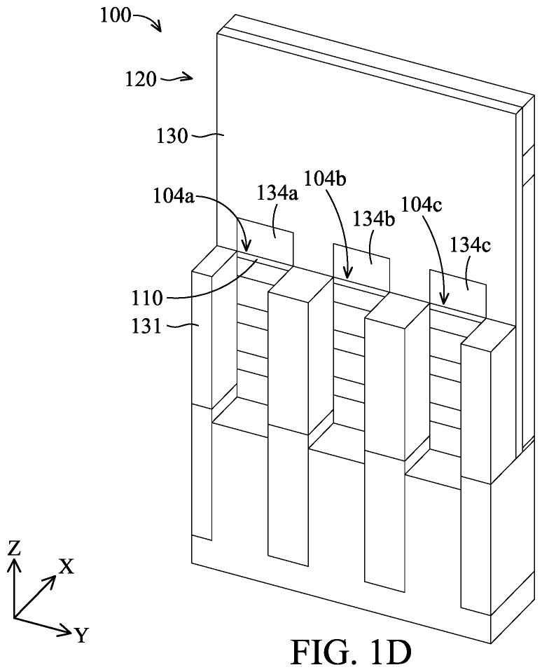

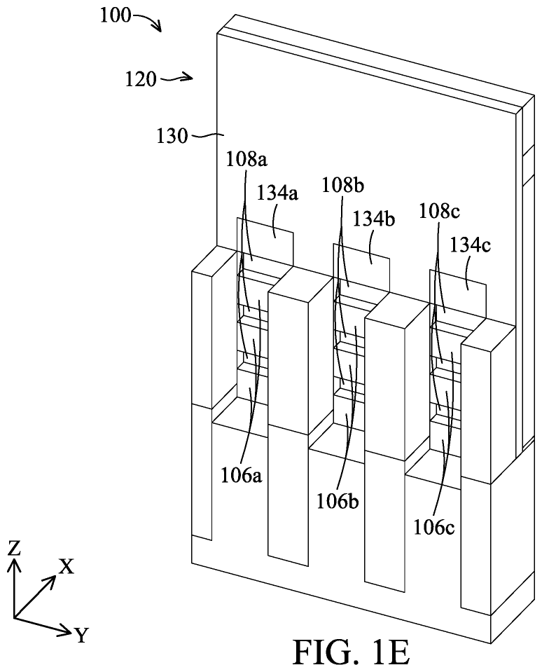

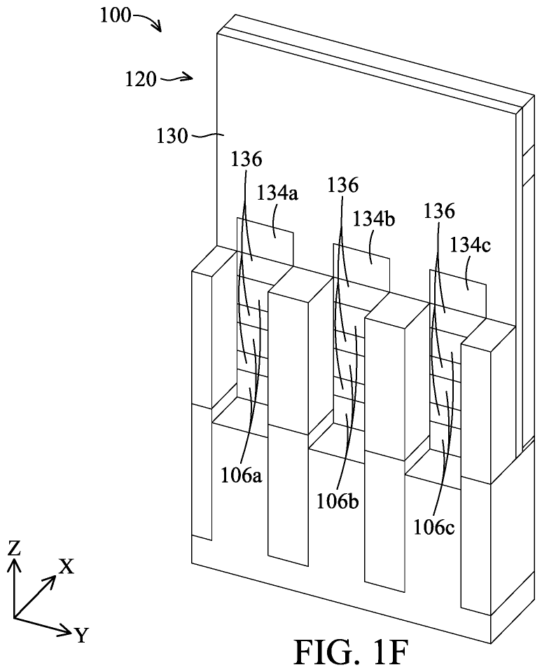

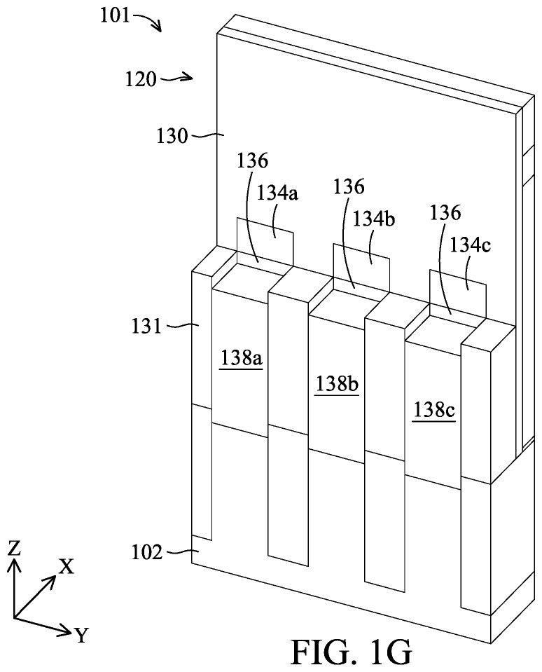

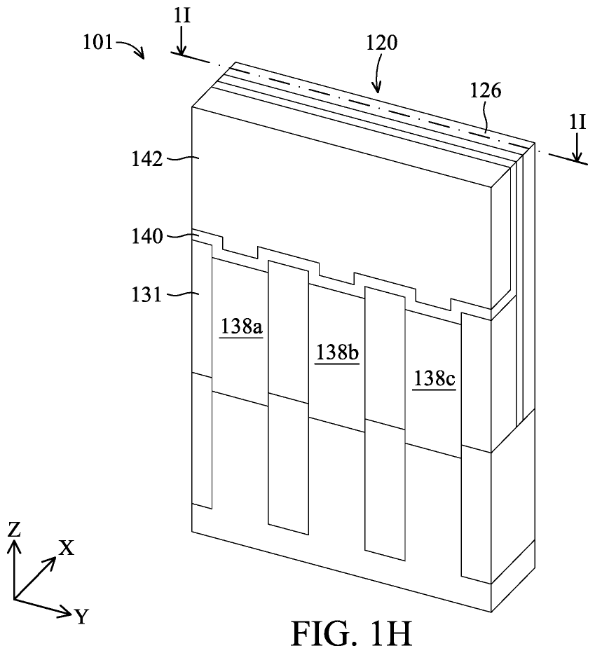

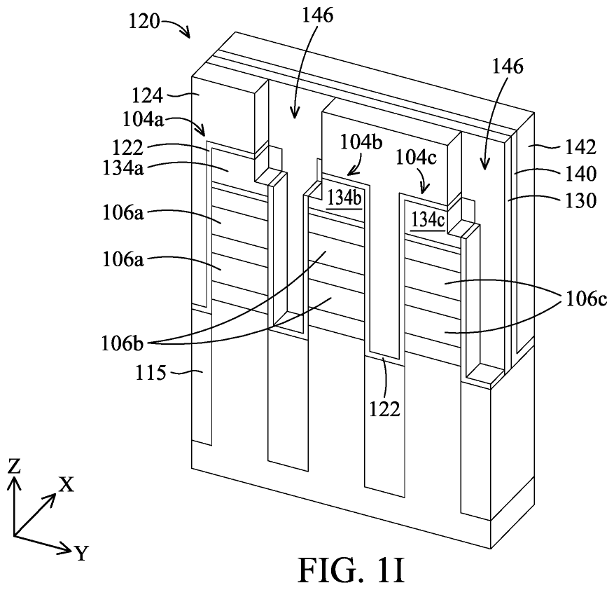

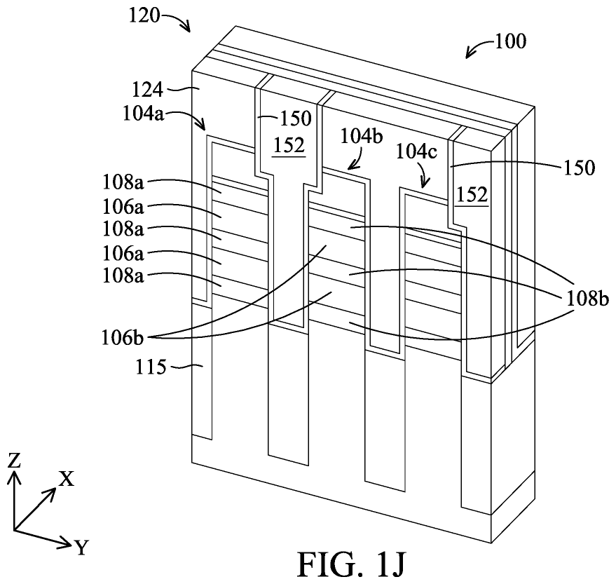

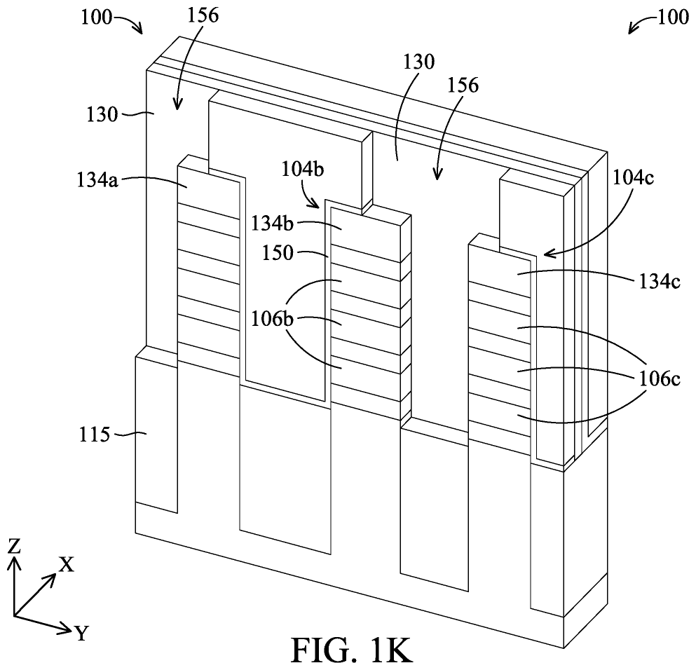

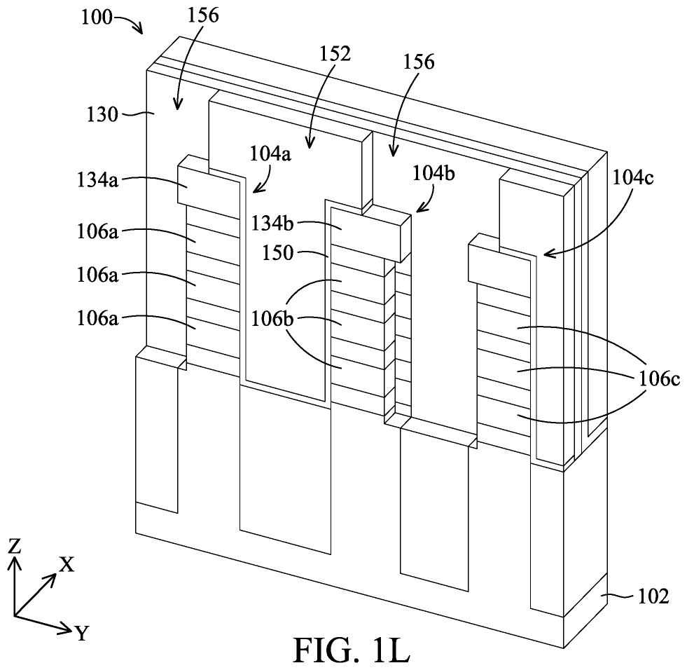

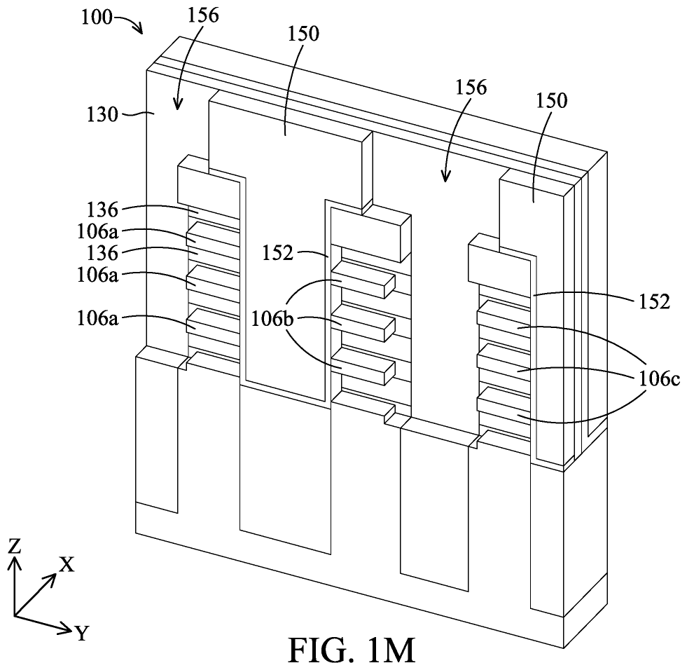

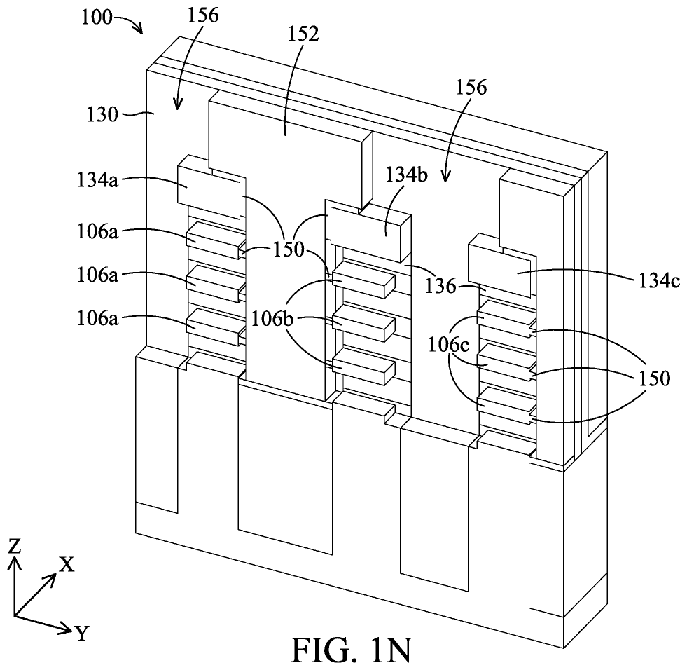

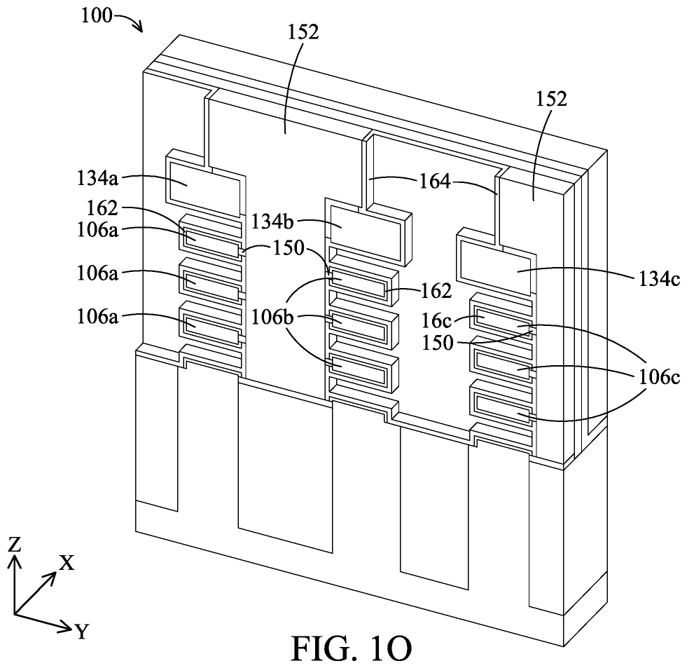

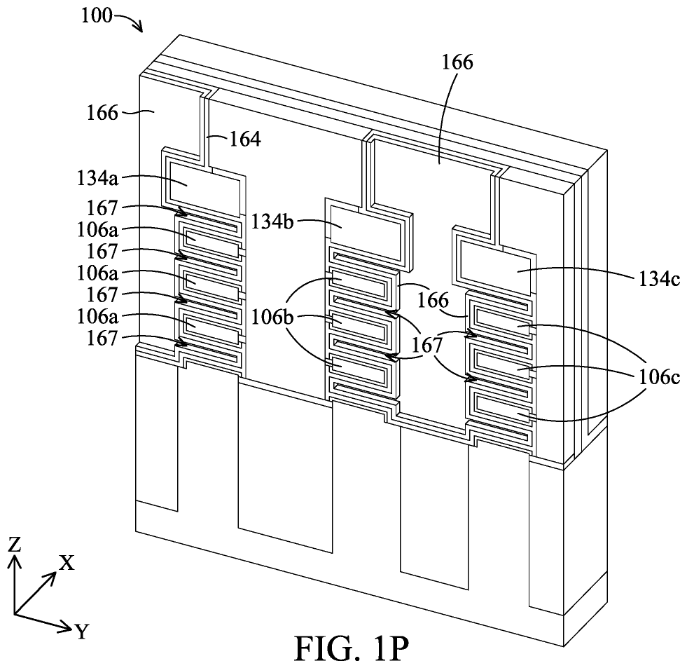

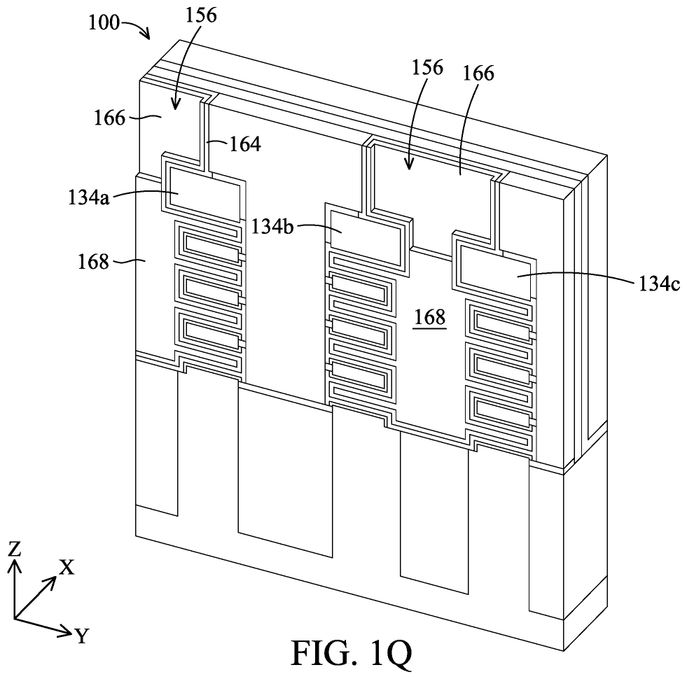

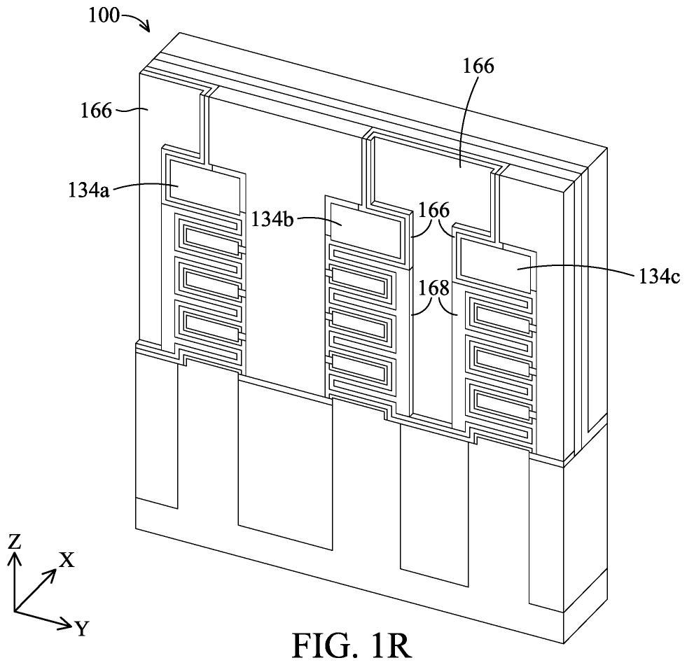

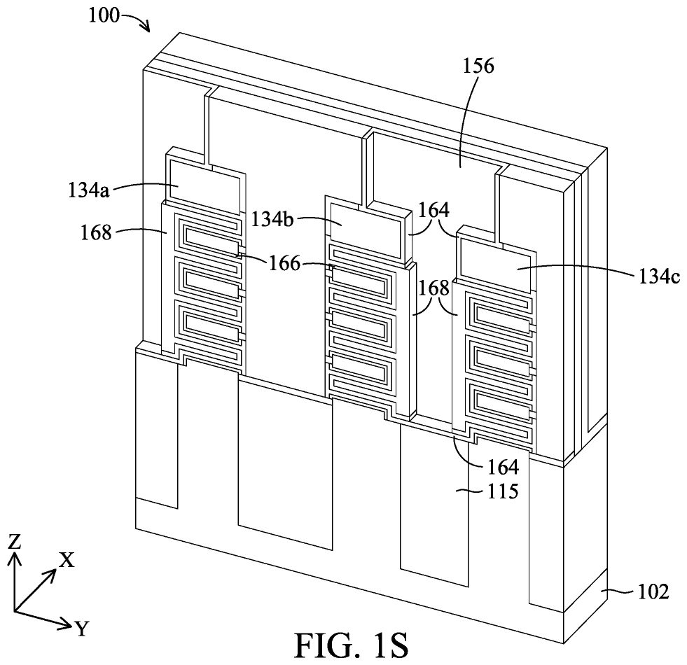

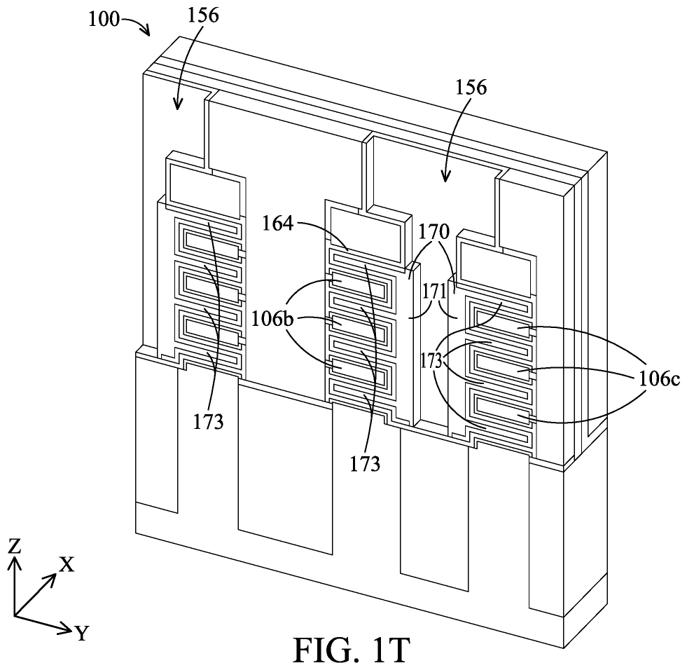

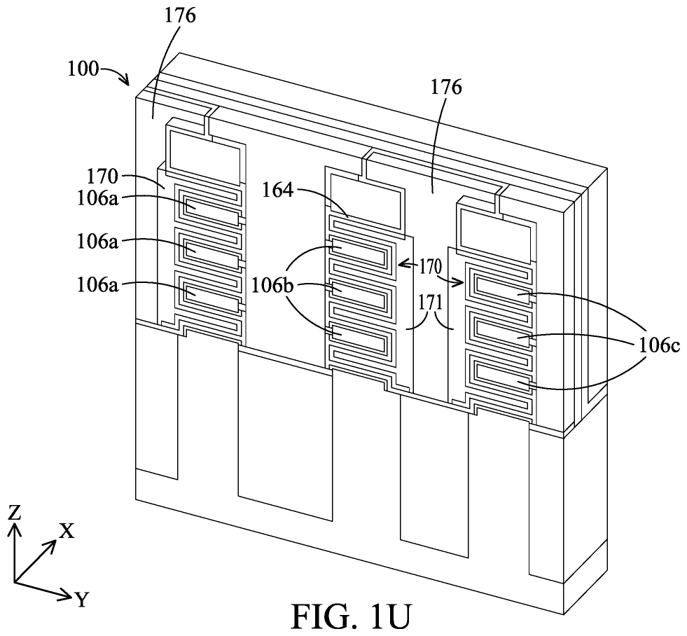

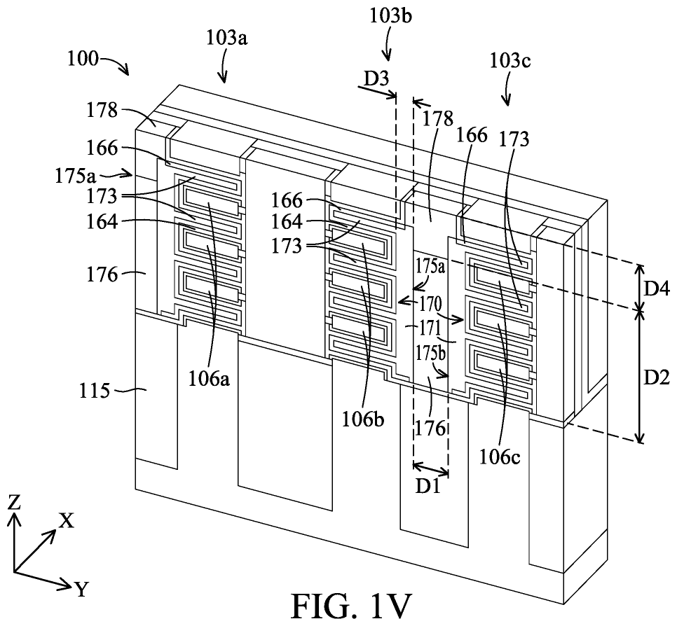

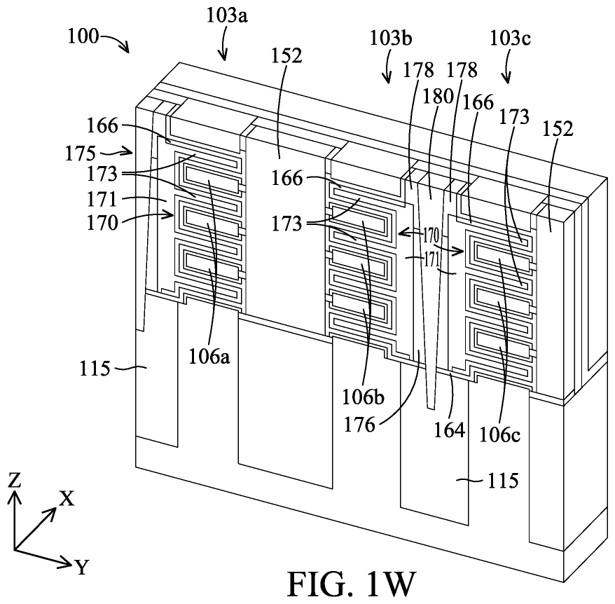

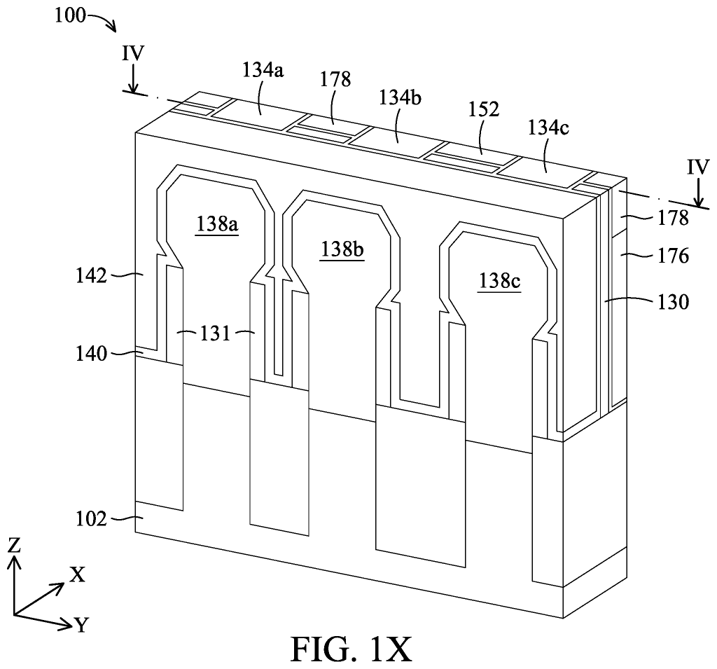

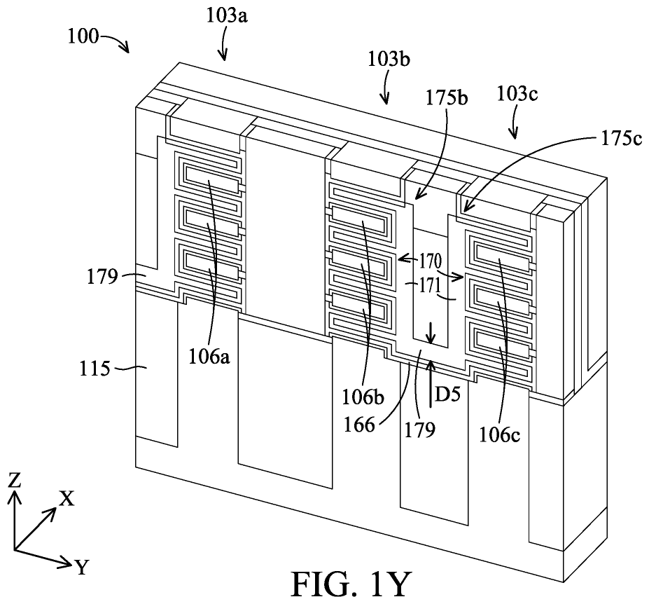

FIGS. 1A-1Y are perspective views of a portion of an integrated circuit 100 fabricated according to some embodiments of the present disclosure. The fabrication process results in a plurality of semiconductor nanostructure transistors, as will be described in further detail below.

FIG. 1A is a perspective view of the integrated circuit 100 at an intermediate state of processing. The integrated circuit 100 includes a substrate 102. The substrate 102 may be a semiconductor substrate, such as a bulk semiconductor, or the like, which may be doped (e.g., with a p-type or an n-type dopant) or undoped. The semiconductor material of the substrate 102 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

The integrated circuit 100 includes a plurality of multilayer stacks 104a-c. Each multilayer stack 104a-c including a plurality of stacked channel 106a-c and sacrificial semiconductor nanostructures 108a-c alternating with each other. Each of the semiconductor stacks 104a-c also includes a respective top sacrificial semiconductor nanostructure 114a-c and a dielectric layer 110a-c. As will be set forth in further detail below, the stacked channels 106a will correspond to stacked channel regions of a nanostructure transistor 103a, the stacked channels 106b will correspond to stacked channel regions of a nanostructure transistor 103b, and the stacked channels 106c will correspond to stacked channel regions of a nanostructure transistor 103c. As set forth in more detail below, the sacrificial semiconductor nanostructures 108a-c will eventually be entirely removed to enable forming gate dielectric and gate metal structures around the stacked channels. The stacked channels may be termed “semiconductor nanostructures”, “semiconductor nanosheets”, “semiconductor nanowires”, or the like.

In the figures, some structures may have reference numbers with a suffix “a”, “b”, or “c”. However, in the description the structures may be referred to without the suffix “a”, “b”, or “c” when there is no distinction being made between features that share the same reference numbers. For example, the stacked channels 106a, 106b, and 106c may be referred to simply as stacked channels 106 in the detailed description when no particular group of stacked channels is being referred to.

The multilayer stacks 104 may initially be formed as a single stack of layers. Subsequently, fin structures may be formed from the single stack of layers by performing a patterning process that etches through the single stack of layers and through the substrate 102 to form the fin structures and recesses in the substrate 102 that can be seen in FIG. 1A. The recesses in the substrate 102 between fin structures can be filled with a trench isolation material 115. The stacks 104 correspond to the fins extending in the X direction. In practice, a plurality of transistors may be formed in each spin. However, for simplicity, the figures illustrate only a portion of each fin corresponding to a location of a single transistor.

The trench isolation regions 115 may be formed by depositing a dielectric material. In some embodiments, the dielectric material is formed over the substrate 102, the stacks 104, and stacked channels 106, and between adjacent stacks 104 and stacked channels 106. The dielectric material may be an oxide, such as silicon oxide, a nitride, the like, or a combination thereof, and may be formed by high-density plasma CVD (HDP-CVD), flowable CVD (FCVD), the like, or a combination thereof. In some embodiments, a liner (not separately illustrated) may first be formed along surfaces of the substrate 102, the stacks 104, and the stacked channels 106. Thereafter, the dielectric material may be formed over the liner of a material such as those discussed above.

In some embodiments, the stacked channels 106 may be formed of a first semiconductor material suitable for semiconductor nanostructure transistors, such as silicon, silicon carbide, or the like. The sacrificial semiconductor nanostructures 108 may be formed of a second semiconductor material that is selectively etchable with respect to the material of the stacked channels 106. For example, the sacrificial semiconductor nanostructures 108 may be formed of silicon germanium or another suitable material that is selectively etchable with respect to the material of the stacked channels 106. In some embodiments, the sacrificial semiconductor nanostructures 108 include silicon germanium with a germanium concentration between 15% and 30%.

In some embodiments, the top sacrificial semiconductor nanostructure 114 includes a semiconductor material that is selectively etchable with respect to the stacked channels 106 and the sacrificial semiconductor nanostructures 108. In one example, the sacrificial semiconductor nanostructure 114 is silicon germanium with a concentration of germanium that is at least 15% greater than the germanium concentration in the sacrificial semiconductor nanostructures 108. For example, the sacrificial semiconductor nanostructure 114 may have a germanium concentration between 30% and 50%, enabling selectively etching the sacrificial semiconductor nanostructure 114 with respect to the sacrificial semiconductor nanostructures 108 and the stacked channels 106.

Due to high etch selectivity between the materials of the stacked channels 106 and the sacrificial semiconductor nanostructures 108, the sacrificial semiconductor nanostructures 108 of the second semiconductor material may be removed without significantly removing the stacked channels 106 of the first semiconductor material, thereby allowing the stacked channels 106 to be released to form channel regions of semiconductor nanostructure transistors. Due to the high etch selectivity between the materials of the sacrificial semiconductor nanostructure 114 and the sacrificial semiconductor nanostructures 108, the sacrificial semiconductor nanostructure 114 can be removed without significantly removing the sacrificial semiconductor nanostructures 108 or the stacked channels 106.

The multilayer stacks 104 may include a cap layer 110. The cap layer 110 can include a semiconductor material such as silicon, silicon carbide, or other suitable materials. Alternatively, the layer 110 can include a dielectric material.

Each of the layers of the multi-layer stack 104 may be epitaxially grown using a process such as chemical vapor deposition (CVD), atomic layer deposition (ALD), vapor phase epitaxy (VPE), molecular beam epitaxy (MBE), or the like.

The multi-layer stack 104 may have different numbers of stacked channels 106 and sacrificial semiconductor nanostructures 108 than are shown in FIG. 1A.

The stacks 104 and the stacked channels 106 may be patterned by any suitable method. For example, one or more photolithography processes, including double-patterning or multi-patterning processes, may be used to form the stacks 104 and the stacked channels 106. Generally, double-patterning or multi-patterning processes combine photolithography and self-aligned processes, allowing for pitches smaller than what is otherwise obtainable using a single, direct photolithography process. As an example of one multi-patterning process, a sacrificial layer may be formed over a substrate and patterned using a photolithography process. Spacers are formed alongside the patterned sacrificial layer using a self-aligned process. The sacrificial layer is then removed, and the remaining spacers may then be used to pattern the stacks 104.

FIG. 1A illustrates the stacks 104 having vertically straight sidewalls. In some embodiments, the sidewalls are substantially vertical (non-tapered), such that width of the stacks 104 and the stacked channels 106 is substantially similar, and the stacked channels 106 are rectangular in shape (e.g., has rectangular profile in the Y-Z plane). In some embodiments, the stacks 104 have tapered sidewalls, such that a width of each of the stacks 104 and/or the stacked channels 106 continuously increases in a direction towards the substrate 102. In such embodiments, the stacked channels 106 may have a different width from each other and be trapezoidal in shape (e.g., have trapezoidal profile in the Y-Z plane).

Though not shown in FIG. 1A, appropriate wells (not separately illustrated) may also be formed in the stacks 104, the stacked channels 106, and/or the trench isolation regions 115. Using masks, an n-type impurity implant may be performed in p-type regions of the substrate 102, and a p-type impurity implant may be performed in n-type regions of the substrate 102. Example n-type impurities may include phosphorus, arsenic, antimony, or the like. Example p-type impurities may include boron, boron fluoride, indium, or the like. An annealing may be performed after the implants to repair implant damage and to activate the p-type and/or n-type impurities. In some embodiments, in situ doping during epitaxial growth of the stacks 104 and the stacked channels 106 may obviate separate implantations, although in situ and implantation doping may be used together.

In FIG. 1B, a sacrificial gate structure 120 has been formed over the stacks 104 and the trench isolation regions 115. The sacrificial gate structure 120 extends in the Y direction. While FIG. 1B illustrates a single sacrificial gate structure 120, in practice, multiple sacrificial gate structures 120 extend across each stack (fin) 104 in the Y direction and are separated from each other by a selected distance. The locations at which the sacrificial gate structures 120 cross a stack 104 correspond to the locations of transistors.

In FIG. 1B, a dielectric layer 122 has been formed prior to forming the sacrificial gate structure 120. The dielectric layer 122 can include a SiO or other suitable dielectric materials. In some embodiments, the dielectric layer 122 has a low K dielectric material. The dielectric layer 122 can be deposited by CVD, ALD, or PVD.

The sacrificial gate structures include a sacrificial gate layer 124 on the sacrificial gate dielectric layer 122. The sacrificial gate layer can include materials that have a high etch selectivity with respect to the trench isolation regions 115. The sacrificial gate layer 124 may be a conductive, semiconductive, or non-conductive material and may be or include amorphous silicon, polycrystalline-silicon (polysilicon), poly-crystalline silicon-germanium (poly-SiGe), metallic nitrides, metallic silicides, metallic oxides, and metals. The sacrificial gate layer 124 may be deposited by physical vapor deposition (PVD), CVD, sputter deposition, or other techniques for depositing the selected material.

The sacrificial gate structure 120 include a dielectric layer 126 on the sacrificial gate layer 124 and a dielectric layer 128 of the dielectric layer 126. The dielectric layers 126 and 128 may correspond to first and second mask layers. The dielectric layer 126 can include silicon nitride, silicon oxynitride, or other suitable dielectric materials. The dielectric layer 126 can include silicon nitride, silicon oxynitride or other suitable dielectric materials. The dielectric layers 126 and 128 are different materials from each other and can be deposited using CVD, ALD. PVD, or other suitable deposition processes. Other materials and deposition processes can be utilized for the dielectric layers 126 and 128 without departing from the scope of the present disclosure.

After deposition of the layers 122, 124, 126, and 128, the dielectric layers 126 and 128 may be patterned to act as a mask layers. An etching process may then be performed in the presence of the patterned dielectric layers in order to etch exposed regions of the sacrificial gate layer 124 and the dielectric layer 122. This results in the structure shown in FIG. 1B.

In FIG. 1C, following formation of the sacrificial gate structure 120, one or more gate spacer layers 130 have been formed covering the sacrificial gate structure 120, the stacks 104, and the trench isolation regions 115. The gate spacer layer 130 can be formed by PVD. CVD, ALD, or other suitable deposition processes. Following formation of the gate spacer layer 130, horizontal portions (e.g., in the X-Y plane) of the gate spacer layer 130 may be removed, thereby exposing upper surfaces of the stacks 104, the substrate 102, and the trench isolation regions 115. The gate spacer layers 130 can include one or more of SiO, SiN, SiON, SiCN, SiOCN, SiOC, or other suitable dielectric materials. Formation of the gate spacer layer 130 may also result in the formation of isolation structures 131 of the same material between adjacent fins 104. Alternatively, the isolation structures 131 may be formed in a separate deposition process in may include a different material than the gate spacer layer 130. Though not shown in FIG. 1C, in practice, the gate spacer layer 130 is also formed on the opposite side of the sacrificial gate structure 120 in the X direction such that the sacrificial gate structure 120 is sandwiched between two gate spacer layers 130 in the X direction.

In FIG. 1C, one or more etching operations have been performed to recess the stacks 104. In particular, the portions of the stacks 104 that are outside the sacrificial gate structures 120 and the gate spacer layer 130 have been removed. Accordingly, the sacrificial gate structures 120 and the gate spacer layer 130 act as a mask for recessing the stacks 104. The recessing of the stacks 104 also results in the recessing of the substrate 102 to a level below the top surface of the trench isolation regions 115. The etching of the stacks 104 may include suitable etch operations for removing materials of the stacked channels 106, the sacrificial semiconductor nanostructures 108, the sacrificial semiconductor nanostructures 114, the layer 110, and the substrate 102. The etching processes can include reactive ion etching (RIE), neutral beam etching (NBE), atomic layer etching (ALE), or the like.

The recesses in the stacks 104 correspond to source/drain trenches. In particular, the source/drain regions will be formed at those locations where the stacks 104 have been recessed, as will be set forth in more detail below.

In FIG. 1D, an etching process has been performed to remove the sacrificial semiconductor nanostructures 114 from a top the stacks 104. Because the sacrificial semiconductor nanostructures 114 are selectively etchable with respect to the material of the sacrificial semiconductor nanostructures 108 and the stacked channels 106, removal of the sacrificial semiconductor nanostructures 114 does not substantially remove the materials of the sacrificial semiconductor nanostructures 108 and the stacked channels 106.

In FIG. 1D, dielectric helmet structures 134 are formed above the stacks 104 in place of the sacrificial semiconductor nanostructures 114. The dielectric helmet structures 134 can include a dielectric material such as SiN, SiCN, SiOCN, SiOC, or other suitable materials. The dielectric helmet structures 134 can be formed by CVD, ALD, PVD, or other suitable deposition processes. After deposition of the material for the dielectric helmet structures 134, and etching process may be performed to remove the material of the dielectric helmet structures 134 from all areas not covered by the sacrificial gate structure 120 and the gate spacer layer 130. This leaves the dielectric helmet structures 134 is shown in FIG. 1D. The dielectric helmet structures 134 can have a thickness between 3 nm and 15 nm. Other materials, thicknesses, and deposition processes can be utilized for the dielectric helmet structures 134 without departing from the scope of the present disclosure.

In some embodiments, at the stage of processing of FIG. 1D, isolation structures 131 remain on the trench isolation regions 115. As will be set forth in more detail below, the isolation structures 131 may be utilized to direct or confine the growth of source/drain regions.

In FIG. 1E, a selective etching process has been performed to recess exposed end portions of the sacrificial semiconductor nanostructures 108 without substantially etching the stacked channels 106. Because the sacrificial semiconductor nanostructures 108 are selectively etchable respect to the stacked channels 106, the recessing process does not substantially etch the stacked channels 106. The recessing process can be performed by a timed etch that etches the sacrificial semiconductor nanostructures 108 to a selected distance in the X direction.

In FIG. 1F, inner spacers 136 are formed by depositing a dielectric material in the recesses between the stacked channels 106 formed by the previous selective etching process. The inner spacer 136 may be a suitable dielectric material, such as silicon carbon nitride (SiCN), silicon oxycarbonitride (SiOCN), or the like, formed by a suitable deposition method such as physical vapor deposition (PVD), CVD, ALD, or the like. An etching process, such as an anisotropic etching process, is performed to remove portions of the inner spacer 136 disposed outside the recesses in the sacrificial semiconductor nanostructures 108. The remaining portions of the dielectric layer correspond to the inner spacers 136 shown in FIG. 1F. Though not apparent in the view of FIG. 1F, recesses and inner spacers 136 are also formed on the other side of the stacks 104 opposite the sacrificial gate structure 120 in the X direction.

In FIG. 1G source/drain regions 138a-c have been formed. In the illustrated embodiment, the source/drain regions 138 are epitaxially grown from exposed portions of the stacked channels 106 and the substrate 102. Initially, the source/drain regions 138 grow between neighboring isolation structures 131. The top surfaces of the source/drain regions 138 are lower than the bottom surfaces of the dielectric helmet structures 134.

For each stack 104, there are two source/drain regions 138. Only a single source/drain structure 138a is apparent in FIG. 1G. This is because the second source/drain structure 138a is on the opposite side of the stacked channels 106a in the X direction and is obscured in the view of FIG. 1GJ. Accordingly, the stacked channels 106a extend in the X direction between two source/drain regions 138a. Likewise, the stacked channels 106b extend in the X direction between two source/drain regions 138b. The stacked channels 106c extend in the X direction between two source/drain regions 138c.

The isolation structures 131 that remain on the trench isolation regions 115 laterally confine the growth of source/drain regions 138 as they grow upward from the stacks 104. In some embodiments, the source/drain regions 138 exert stress in the respective stacked channels 106, thereby improving performance. The source/drain regions 138 are formed such that each sacrificial gate structure 120 is disposed between respective neighboring pairs of the source/drain regions 138. In some embodiments, the spacer layer 130 and the inner spacers 136 separate the source/drain regions 138 from the sacrificial gate layer 124 by an appropriate lateral distance (e.g., in the X-axis direction) to prevent electrical bridging to subsequently formed gates of the resulting device.

The source/drain regions 138 may include any acceptable material, such as appropriate for n-type or p-type devices. For n-type devices, the source/drain regions 138 include materials exerting a tensile strain in the channel regions, such as silicon, SiC, SiCP, SiP, or the like, in some embodiments. When p-type devices are formed, the source/drain regions 138 include materials exerting a compressive strain in the channel regions, such as SiGe, SiGeB, Ge, GeSn, or the like, in accordance with certain embodiments. The source/drain regions 138 may have surfaces raised from respective surfaces of the fins and may have facets. Neighboring source/drain regions 138 may merge in some embodiments to form a singular source/drain region 138 over two neighboring fins of the stacks 104.

The source/drain regions 138 may be implanted with dopants followed by an annealing process. The source/drain regions 138 may have an impurity concentration of between about 10¹⁹ cm⁻³ and about 10²¹ cm⁻³. N-type and/or p-type impurities for source/drain regions 138 may be any of the impurities previously discussed. In some embodiments, the source/drain regions 138 are in situ doped during growth.

In FIG. 1H, a contact etch stop layer (CESL) 140 and an interlevel dielectric (ILD) 142 have been formed. The CESL layer 140 can include a thin dielectric layer can formally deposited on exposed surfaces of the source/drain regions 138, the isolation structures 122, the isolation structures 131, and the trench isolation regions 115. The CESL layer 140 can include SiN, SiC, SiOC, SiOCN, SiON, or other suitable dielectric materials. The CESL 140 can be deposited by CVD, ALD, PVD, or other suitable deposition processes.

The dielectric layer 142 covers the CESL 140. The dielectric layer 142 can include SiO, SiON, SiN, SiC, SiOC, SiOCN, SiON, or other suitable dielectric materials. The dielectric layer 142 can be deposited by CVD, ALD, PVD, or other suitable deposition processes.

In FIG. 1H, a chemical mechanical planarization (CMP) process has been performed. The CMP process removes the dielectric layers 126 and 128 of the sacrificial gate structure 120. The CMP process reduces the height of the gate spacer layer 130 and the polysilicon layer 124.

The view of FIG. 1I is taken on cut lines 1I of FIG. 1H. Accordingly, the view of FIG. 1I is taken through a Y-Z plane through the sacrificial gate structure 120 and the stacks 104. Accordingly, the stacked channels 106 and the remaining portions of the sacrificial semiconductor nanostructures 108 are visible in FIG. 1I.

In FIG. 1I, an etching process has been performed to remove portions of the polysilicon layer 124 between the stacks 104a and 104b. In particular, the etching process forms a trench 146 and the layer 124 having a wide the upper portion and a narrow lower portion. The wide upper portion may correspond to the width of the opening in a mask layer utilized to form the trenches 146. However, the etching through the dielectric helmet structures 134 may be significantly slow such that the trench has been etched only partway through the dielectric helmet structures 134 by the time of the trench has etched all the way to the trench isolation region 115. Accordingly, after the etching process, the dielectric helmet structures 134 are missing an upper corner.

In FIG. 1J, a dielectric layer 150 has been formed lining the walls and floor of the trenches 146. In one embodiment, the dielectric layer 150 includes silicon oxide. However, the dielectric layer 150 can alternatively include SiON, SiN, SiC, SiOC, SiOCN, SiON, or other suitable dielectric materials. The dielectric layer 150 can be deposited by CVD, ALD, PVD, or other suitable deposition processes. The dielectric layer 150 is in contact with the stacked channels 106a and 106b and the sacrificial semiconductor nanostructures 108a and 108b.

In FIG. 1J, a dielectric wall structure 152 has been formed in the trenches 146 in contact with the dielectric layer 150. The dielectric wall structure 152 corresponds to an isolation structure or barrier structure between adjacent transistors. Furthermore, the dielectric wall structure 152 is separated from the stacked channels 106 only by the dielectric layer 150. The dielectric wall structure 152 can include SiON, SiN, SiC, SiOC, SiOCN, SiON, or other suitable dielectric materials. The dielectric wall structure 152 can be deposited by CVD, ALD, PVD, or other suitable deposition processes.

In FIG. 1K, the remaining portions of the layer 124 have been removed, resulting in trenches 156. The trench 156 is formed between the stacks 104c and 104c. The trenches 156 can be formed without a mask as the wall structures 152 are not etched by the same etching process that etches the layer 124. FIG. 1K also illustrates some differences from the embodiment shown in FIG. 1J. In particular, in the alternative example of FIG. 1K, the dielectric helmet structures 134 are not partially etched by the formation of the trenches 146. Accordingly, the step structure is not present in the dielectric helmet structures 134 in FIG. 1K. Additionally, FIG. 1K illustrates three stacked channels 106 in each stack 104 or as FIG. 1J illustrative only two stacked channels 106 in each stack 104.

In FIG. 1L, a recessing process has been performed to recess the stacked channels 106 and sacrificial semiconductor nanostructures 108 in the trenches 156 in the Y direction. The result is that the dielectric helmet structures 134 extend further in the Y direction than do the stacked channels 106 and the sacrificial semiconductor nanostructures 108. This has the effect of increasing the lateral distance in the Y direction between the stacked channels 106b and the stacked channels 106c.

In FIG. 1M, stacked channels 106 are released by removal of the sacrificial semiconductor nanostructures 108. The sacrificial semiconductor nanostructures 108 are removed to release the stacked channels 106. The sacrificial semiconductor nanostructures 108 can be removed by a selective etching process using an etchant that is selective to the material of the sacrificial semiconductor nanostructures 108, such that the sacrificial semiconductor nanostructures 108 are removed without substantially etching the stacked channels 106. In some embodiments, the etching process is an isotropic etching process using an etching gas, and optionally, a carrier gas, where the etching gas comprises F2 and HF, and the carrier gas may be an inert gas such as Ar, He, N2, combinations thereof, or the like. In some embodiments, the sacrificial semiconductor nanostructures 108 are removed and the stacked channels 106 are patterned to form channel regions of both PFETs and NFETs.

In FIG. 1N, the dielectric layer 150 is etched such that the dielectric layer 150 is entirely removed at locations vertically between stacked channels 106. However, portions of the dielectric layer 150 remain laterally between stacked channels 106 and the wall structure 152 and on the dielectric helmet structures 134.

In FIG. 1O, a gate dielectric has been formed on the stacked channels 106. The gate dielectric includes an interfacial gate dielectric layer 162 and a high-K gate dielectric layer 164. The interfacial gate dielectric layer 162 is deposited on all exposed surfaces of the stacked channels 106. The interfacial gate dielectric layer 162 can include a dielectric material such as silicon oxide, silicon nitride, or other suitable dielectric materials. The interfacial gate dielectric layer 162 can include a comparatively low-K dielectric with respect to high-K dielectric such as hafnium oxide or other high-K dielectric materials that may be used in gate dielectrics of transistors. High-K dielectrics can include dielectric materials with a dielectric constant higher than the dielectric constant of silicon oxide. The interfacial gate dielectric layer 162 can be formed by a thermal oxidation process, a chemical vapor deposition (CVD) process, or an atomic layer deposition (ALD) process. The interfacial gate dielectric layer 162 can have a thickness between 0.5 nm and 2 nm. Other materials, deposition processes, and thicknesses can be utilized for the interfacial gate dielectric layer 162 without departing from the scope of the present disclosure.

In FIG. 1O, a high-K dielectric layer 164 has been deposited. The high-K dielectric layer 164 is deposited in a conformal deposition process. The conformal deposition process deposits the high-K dielectric layer 164 on the interfacial gate dielectric layer 162, and on the exposed surfaces of the wall structure 152. The high-K dielectric layer 164 is also deposited on sidewalls of the gate spacer layers 130. The high-K gate dielectric layer 164 surrounds the stacked channels 106, aside from the small portion of each channel 106 covered by the dielectric layer 150. The high-K gate dielectric layer 164 has a thickness between 1 nm and 3 nm. The high-K dielectric layer includes one or more layers of a dielectric material, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The high-K dielectric layer 164 may be formed by CVD, ALD, or any suitable method. Other thicknesses, deposition processes, and materials can be utilized for the high-K dielectric layer 164 without departing from the scope of the present disclosure.

In FIG. 1P, a thin gate metal 166 has been deposited. The gate metal 166 is deposited on all exposed surfaces of the high-K dielectric layer 164. The gate metal 166 substantially surrounds stacked channels 106. The gate metal 166 is positioned around three sides of each stacked channel 106. The thin gate metal 166 is on the top side, the bottom side, and the left lateral side of each stacked channel 106a. The thin gate metal 166 is on the top side, the bottom side, and the right lateral side of each stacked channel 106b. The thin gate metal 166 is on the top side, the bottom side, and the left lateral side of each stacked channel 106c.

The thin gate metal 166 does not entirely fill the space above and below each stacked channel 106. Accordingly, there is a gap 167 between adjacent stacks channels 166. As an example, there is a gap 167 between the portion of the gate metal 166 on the bottom of the top stacked channel 106a and the portion of the top of the middle channel 106a, and so forth. Furthermore, there is a gap between the portion of the gate metal on top of each top stacked channel 106 and the portion of the gate metal on the bottom of the dielectric helmet structure 134. The thickness of the gate metal 166 can be between 0.5 nm and 2 nm.

Although the gate metal 166 is shown as a single layer in FIG. 1P, in practice, the gate metal 166 can include one or more conductive liner layers, work function layers, and gate fill layers that collectively make up the gate metal. The gate metal 166 can include one or more of Ti, TiN, Ta, TaN, Al, Cu, Co, Ru, W, Au, or other suitable conductive materials. The gate metal 166 can be deposited by PVD, ALD, or CVD. Other configurations, materials, and deposition processes can be utilized for the gate metal 166 without departing from the scope of the present disclosure.

In FIG. 1Q, a bottom antireflective coating (BARC) layer 168 has been deposited in the trenches 156. The BARC layer 168 can include SiCOH or another suitable material. The BARC layer 168 fills the gaps 167 between portions of the gate metal 166 between stacked channels 106 and below the dielectric helmet structure 134. The BARC layer can include a dielectric material, a conductive material, or other types of materials. An etchback process can be performed to reduce the height of the BARC layer within the trenches 156 to a level intermediate to the top and bottom surfaces of the dielectric helmet structures 134. The BARC layer can be deposited by ALD, CVD, PVD, or other suitable deposition processes.

In FIG. 1R, and etching process has been performed to remove portions of the BARC layer 168 that are not directly below the portions of the gate metal 166 that are on sidewalls of the dielectric helmet structures 134. Accordingly, sidewalls of the BARC layer 168 are flush with sidewalls of the portion of the gate metal 166 on the lateral sides of the dielectric helmet structures 134.

In FIG. 1S, an etching process has been performed to remove the gate metal 166 from all locations that are not protected by the BARC layer 168. Accordingly, the etching process selectively etches the gate metal 166 with respect to the BARC layer 168. Accordingly, the gate metal 166 still remains on three sides of each channel region 106 and below each helmet structure 134. A portion of the gate metal 166 remains at the bottom of the trenches 126 directly below the remaining portions of the BARC layer 168.

In FIG. 1T, the BARC layer 168 has been entirely removed and a gate metal 170 has been deposited. The gate metal 170 fills the gaps between stacked channels 106. The gate metal 106 can be formed in a deposition process that selectively deposits the material of the gate metal 170 on exposed portions of the gate metal 166. The selective deposition process can include an ALD process or another suitable deposition process. Accordingly, the gate metal 170 does not fill the trenches 156. The gate metal 170 can include W, Ru, Mo, Ti, TiN, or other suitable conductive materials. The gate metal 170 can have a thickness between 2 nm and 15 nm, though other thicknesses can be utilized without departing from the scope of the present disclosure.

The gate metal 170 includes, at each stack 104, a vertical column 171 and finger portions 173 extending laterally from the vertical column 171 into the spaces between stacked channels 106 and below the helmet portions 134. The vertical column 171 extends from a bottom of the trench 156 to a level substantially even with a lower surface of the portion of the high-K gate dielectric 164 on the bottom side of the dielectric helmet structures 134.

The selective growth process is highly advantageous because it causes the gate metal 170 to fill the gaps between channels 106 but not completely fill the space between adjacent sets of stacked channels 106. For example, there is a gap between the portion of the gate metal 170 around the stacked channels 106b and the portion of the gate metal 170 around the stacked channels 106c. The result of this is a tremendous reduction in the capacitance between the gate electrode (made up of the gate metal 166 and 170) of each transistor and the source/drain regions 138 or source/drain contact metals. This results in better functioning transistors and overall circuits.

In FIG. 1U, a wall structure 176 has been formed in the trenches 156. In particular, the wall structure 176 is formed between vertical column portions 171 of the gate metal 170 of adjacent sets of stacked channels 106. The wall structure 176 can include silicon oxide, SiON, SiN, SiC. SiOC, SiOCN, SiON, or other suitable dielectric materials. The wall structure 176 can be deposited by CVD, ALD, or PVD. After deposition of the wall structure 176, a CMP process can be performed.

In FIG. 1V, an etchback process has been performed to reduce the height of the wall structure 176 to a level below a top surface of the gate metal 170. A gate coupling structure 178 is then deposited in place of the removed portion of the wall structure 170. The gate coupling structure 178 may correspond to coupling structures that electrically couple the gate metal 170 of two adjacent transistors. The gate coupling structure 178 is in direct contact with the gate metal 170. A CMP process can then be performed to planarize the top of the gate metal 170. The gate metal 170 can include aluminum, titanium, tungsten, or other suitable conductive materials. The gate metal 170 can be deposited by PVD, ALD, CVD, or other suitable deposition processes.

At the stage of processing shown in FIG. 1V, transistors 103a-c are substantially complete. The transistor 103a includes stacked channels 106a extending between the source/drain regions 138a and acting as stacked channels of the transistor 103a. The gate metals 166 and 170 (including column portion 171 and fingers 173) adjacent to the stacked channels 106a correspond to a gate electrode 175a of the transistor 103a. The gate electrode 175a is positioned on a top side, a bottom side, and a left lateral side of the stacked channels 106a. The gate electrode 175a is not positioned on the right lateral side of the stacked channels 106a.

The transistor 103b includes stacked channels 106b extending between the source/drain regions 138b and acting as stacked channels of the transistor 103b. The gate metals 166 and 170 (including column portion 171 and fingers 173) adjacent to the stacked channels 106b correspond to a gate electrode 175b of the transistor 103b. The gate electrode 175b is positioned on a top side, a bottom side, and a right lateral side of the stacked channels 106b. The gate electrode 175b is not positioned on the left lateral side of the stacked channels 106b.

The transistor 103c includes stacked channels 106c extending between the source/drain regions 138c and acting as stacked channels of the transistor 103c. The gate metals 166 and 170 (including column portion 171 and fingers 173) adjacent to the stacked channels 106c correspond to a gate electrode 175c of the transistor 103c. The gate electrode 175a is positioned on a top side, a bottom side, and a left lateral side of the stacked channels 106c. The gate electrode 175c is not positioned on the right lateral side of the stacked channels 106c.

in FIG. 1V, the gate electrode 175b is electrically coupled to the gate electrode 175c by the gate coupling metal 178. However, in practice, the gate electrode 175b may or may not be electrically coupled to the gate electrode 175c depending on the particular circuit layout to be implemented.

The wall structure 176 has a width dimension D1 in the Y direction between adjacent gate electrodes (e.g., between 175b and 175c). The dimension D1 can be between 5 nm and 40 nm. The wall structure 176 has a height dimension D2 in the Z direction. The dimension D2 can be between 15 nm and 70 nm. The wall structure 176 can have a thickness dimension in the X direction between 5 nm and 20 nm.

The vertical column portion 171 of the gate metal 170 can have a width dimension in the Y direction between 2 nm and 10 nm. The gate coupling metal 178 can have a height dimension D4 in the Z direction between 5 nm and 20 nm. Other dimensions can be utilized without departing from the scope of the present disclosure.

The combination of the wall structure 152, the wall structure 176, and the dielectric helmet structure 134 on both lateral sides and the top side of the stacked channels 106 of a transistor 103 correspond to a dielectric all around (DAA) structure. This can greatly reduce the gate to source/drain capacitance, as set forth previously. Furthermore, other potential transistor structures include a gate metal stack above the stacked channels. However, in the embodiment of FIG. 1Y, instead of a gate metal stack above the stacked channels 106, there is a helmet structure 134 in close proximity and directly above the top stacked channel 106. This can lead to the great reduction in the height of the gate stack and, correspondingly, in the capacitance between gate electrodes 175 and source/drain structures.

FIG. 1W illustrates a cut metal gate structure 180, in accordance with some embodiments. The cut metal gate structure 180 can be implemented at the locations where it is desirable to electrically isolate the gate electrodes 175 of adjacent transistors. The cut metal gate structure can be formed by etching through the gate coupling metal 178, the wall structure 176, and a portion of the trench isolation region 115. A dielectric material can be deposited in the trench. The cut metal gate structure 180 can include silicon oxide, SiON, SiN, SiC, SiOC, SiOCN, SiON, or other suitable dielectric materials.

FIG. 1X illustrates the integrated circuit 100 of FIG. 1V from a Y-Z cut plane extending through the interlevel dielectric layer 142 and the source/drain regions 138. The cut lines 1V illustrates a relative position of the view of FIG. 1V. The view of FIG. 1X illustrates that end portions of the source/drain regions 138 can have a hexagonal, octagonal, or circular shape near a top portion.

FIG. 1Y illustrates an integrated circuit 100 at the stage of processing shown in FIG. 1V, though with an adjustment to the gate metals 170 and 166. In particular, the gate metal 166 extends unbroken along a bottom of the trench 156 between adjacent sets of stacked channels. During the selected deposition of the gate metal 170, the gate metal 170 grows to extend across the bottom of the trench as well, forming a bottom portion 179. The bottom portion 179 can electrically couple the gate electrodes 175b and 175c. the bottom portion 179 can have a thickness dimension D5 between 2 nm and 15 nm, though other thicknesses can be utilized without departing from the scope of the present disclosure. In FIG. 1Y, the gate metals 170 forms a U-shape structure, with the bottom portion 179 and the column portions 171.

In some embodiments, the helmet structures 134 can be entirely removed. For example, a CMP process can be performed in a manner that entirely removes the helmet structures 134. Alternatively, the helmet structures 134 can be removed in an alternate manner.

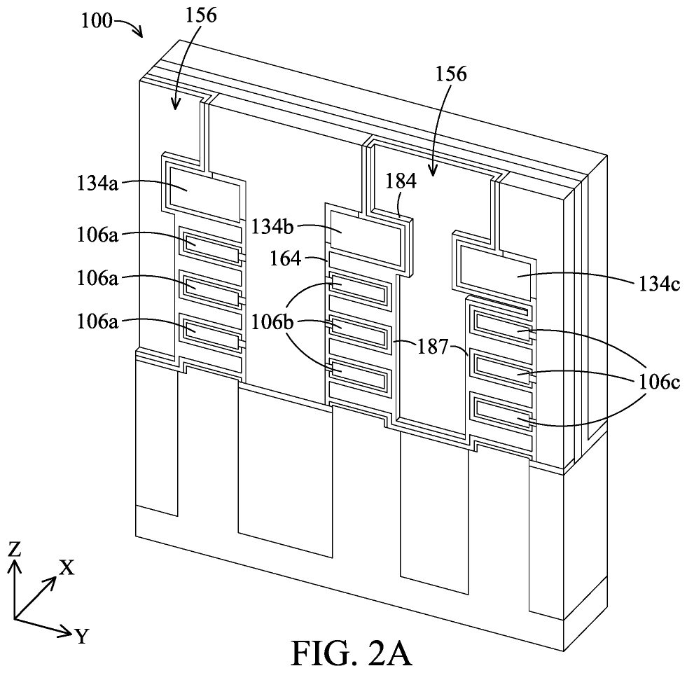

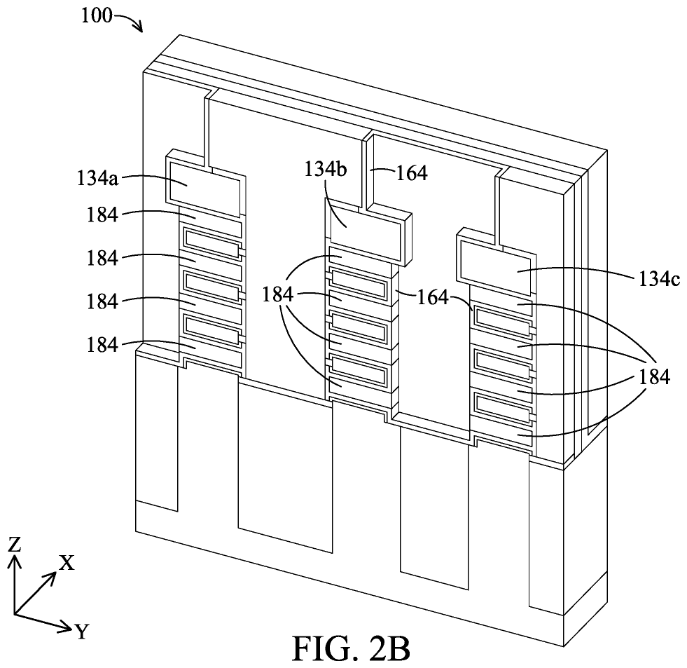

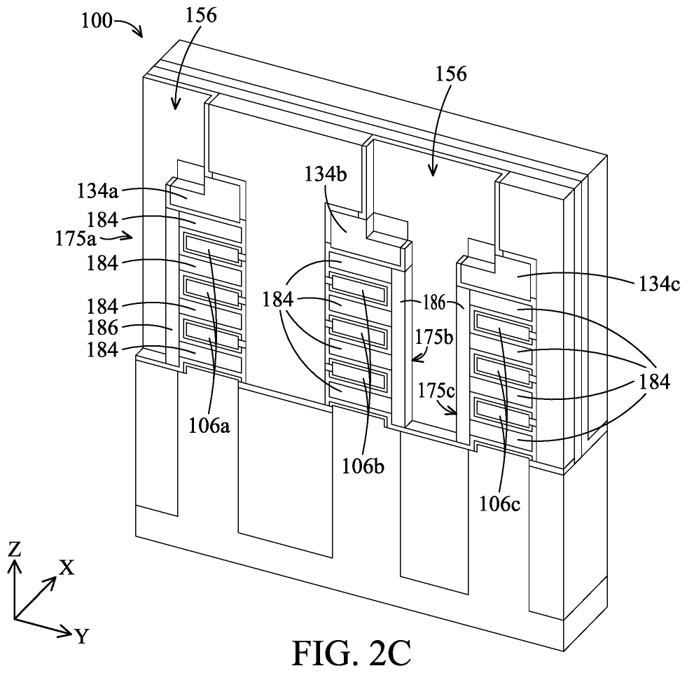

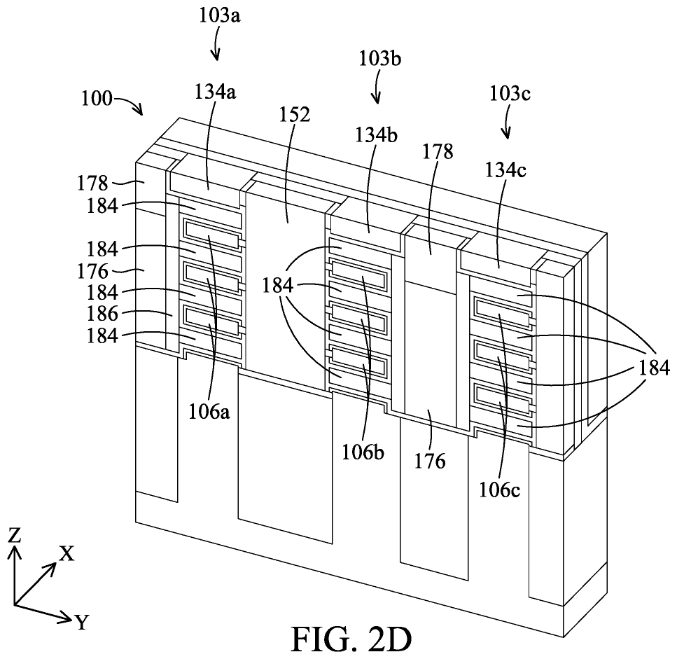

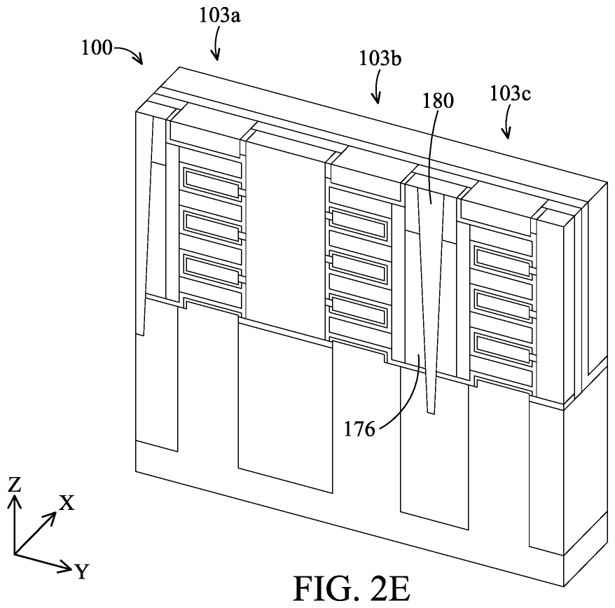

FIGS. 2A-2E are perspective views of an integrated circuit 100 at various stages of processing, in accordance with some embodiments. The process for forming the integrated circuit 100 prior to the stage shown in FIG. 2A can be the same as shown in FIGS. 1A-1O. In FIG. 2A, a gate metal 184 has been deposited the high-K gate dielectric layer 164. The gate metal 184 entirely fills the remaining space between vertically adjacent stacked channels 106 and below the dielectric helmet structures 134. The gate metal 184 can include one or more of Ti, TiN, Ta, TaN, Al, Cu, Co, Ru, W, Au, or other suitable conductive materials. The gate metal 184 can be deposited by PVD, ALD, CVD, or other suitable deposition processes.

In FIG. 2B, an etching process has been performed. The etching process removes the gate metal 184 from the trench 156 at locations extending beyond the surface of the high-K gate dielectric layer 164 on lateral surfaces of the stacked channels 106.

In FIG. 2C, a gate metal 186 has been deposited in a similar position as the BARC layer 168 described in relation to FIG. 1Q. The gate metal 186 has been etched back in a manner similar to how the BARC layer 168 has been etched back as described in relation to FIG. 1R in order to form a protective layer for etching the gate metal 184. The gate metal 184 has been etched substantially as described for etching of the gate metal 166 in FIG. 1S, but using the gate metal 186 as a protective layer rather than the BARC layer 168. The result is that the gate metal 184 remains only above and below the stacked channels 106. The dielectric helmet structures 134 have also been etched as described in relation to FIG. 1I.

In some embodiments, the gate metal 184 may have relatively poor etch selectivity with respect to other materials including the semiconductor material of the substrate 102 and channels 106, and the dielectric materials of the trench isolation regions, the high-K gate dielectric layer 164, the helmet structures 134, and other structures. Accordingly, in some embodiments it is beneficial to deposit the gate metal 186 to form column regions of the gate electrode because the gate metal 186 may have better etch selectivity with respect to the other materials present than does the gate metal 184. Accordingly, the gate metal 186 can be anisotropically etched to form the column regions without unduly etching other structures. Nevertheless, in some embodiments the gate metal 184 may be used to form the column portions of the gate electrode without depositing the gate metal 186.

The gate metal 186 can include W, Ru, Mo, Ti, TiN, or other suitable conductive materials. The gate metal 186 can be deposited by CVD, PVD, ALD, or other suitable deposition processes. The result is that gate electrodes 175 are formed. The gate metal 186 is a vertical column similar to the vertical column 171. The gate metal 184 corresponds to finger portions similar to the finger portions 173.

In some embodiments, the bottom portion 179 of the gate metal can be formed at the bottom of the trench 156, as described in relation to FIG. 1Y. This results in a U-shaped gate structure as described in relation to FIG. 1Y.

In FIG. 2D, the wall structure 176 has been deposited and recessed and the gate coupling structures 178 have been formed, substantially as described in relation to FIGS. 1U and 1V. At the stage shown in FIG. 2D, processing of the transistors 103 is substantially complete. The transistors 103 of FIG. 2D are similar to the transistors 103 of FIG. 1V, except that the structures of the gate metals 184 and 186 differ from the structure of the gate metals 166 and 170, as described previously.

In FIG. 2E, the cut metal gate structure 180 has been formed between the transistors 103b and 103c substantially as described in relation to FIG. 1W.

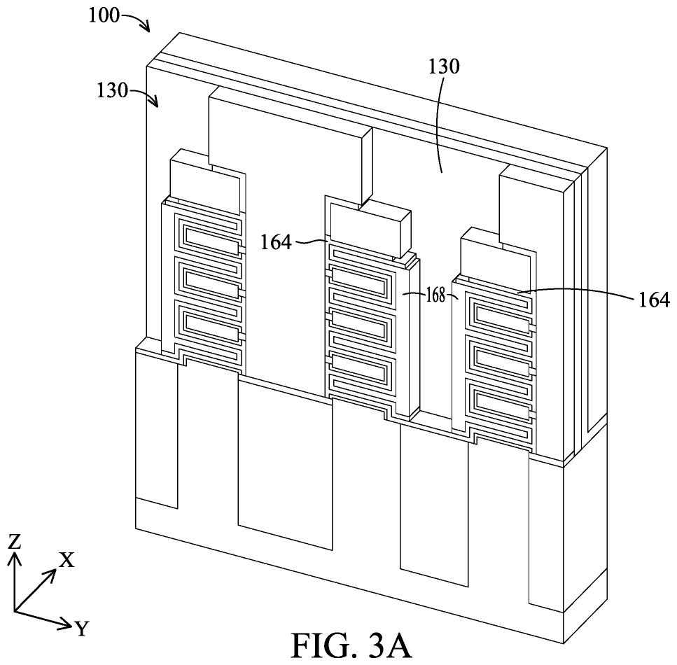

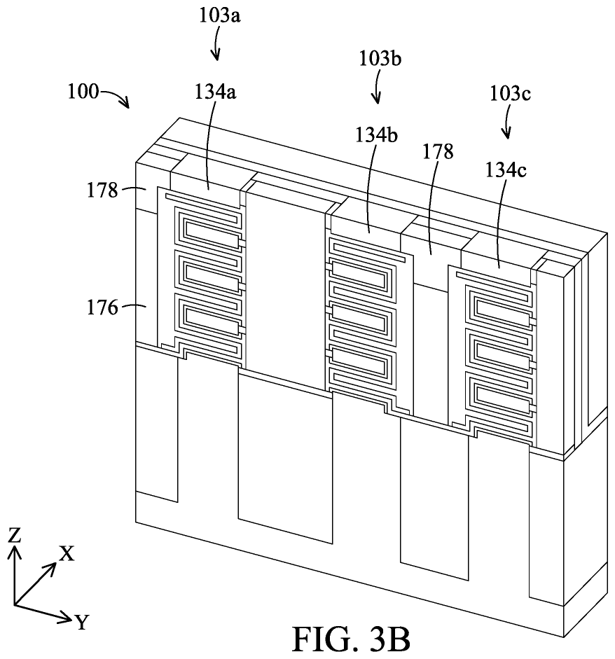

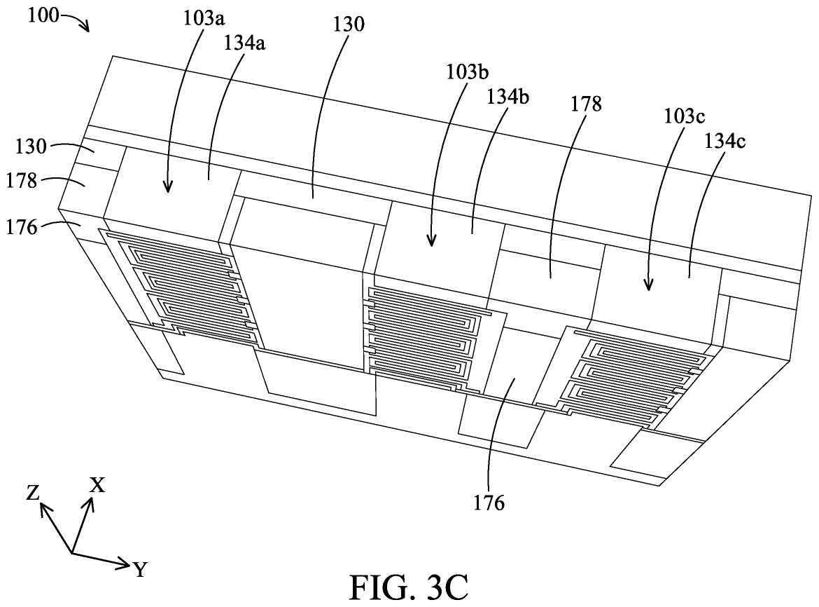

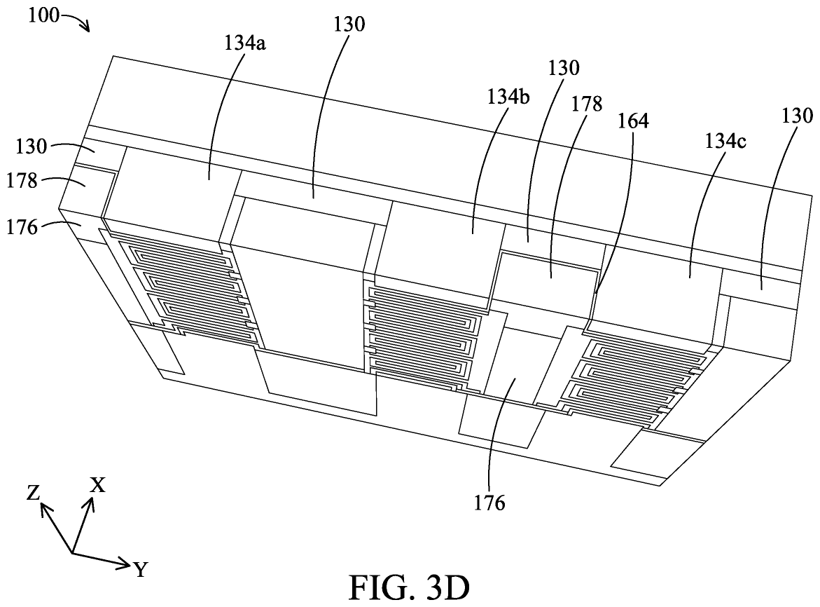

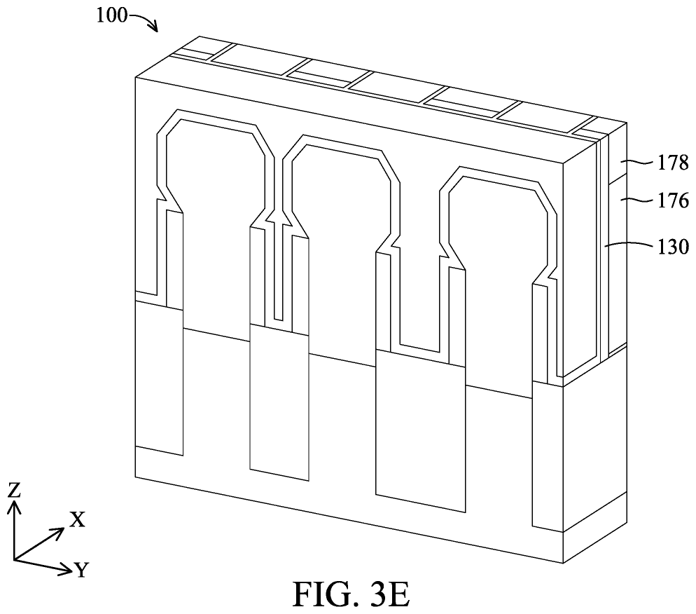

FIG. 3A is a perspective view of an integrated circuit 100 at a stage of processing substantially similar to the stage of processing shown in FIG. 1S, except that an etching process has been performed to remove the high-K gate dielectric layer 164 at locations that are not protected by the BARC layer 168, in accordance with some embodiments. The result is that the gate spacer layer 130 is again visible after removal of the high-K gate dielectric layer 164.

In FIG. 3B, processing of the transistors 103 is substantially complete, using the process is implemented between FIGS. 1S and 1V, but with the removal of the high-K gate dielectric layer 164 as described in relation to FIG. 3A.

FIG. 3C is a view of the integrated circuit 100 at the stage of processing of FIG. 3B, but from a more elevated perspective view. From the view of FIG. 3C, a can be more readily discerned that in the absence of the high-K gate dielectric 164, the gate coupling structures 178 directly but the dielectric helmet structures 134.

FIG. 3D is a view of the integrated circuit 100 at the stage of processing and from the same view of FIG. 3C, except that the high-K gate dielectric 164 was not removed. Accordingly, the integrated circuit 100 of FIG. 3D corresponds to the integrated circuit 100 of FIG. 1V, but from the more elevated perspective view of FIG. 3C. The contrast between FIG. 3C and 3D helps to illustrate the locations from which the high-K gate dielectric has been removed. Though not shown, the high-K gate dielectric 164 can also be removed at the stage of processing shown in FIG. 2C. Accordingly, in some embodiments, the structure of Figures of 2D and 2E can be produced, but with the removal of the high-K gate dielectric 164 as described in relation to FIG. 3A. In some embodiments, the helmet structures 134 can be entirely removed. For example, a CMP process can be performed in a manner that entirely removes the helmet structures 134. Alternatively, the helmet structures 134 can be removed in an alternate manner.

FIG. 3E is a view of the integrated circuit 100 of FIG. 3B, the from a view similar to that shown in FIG. 1X. The view of FIG. 3E illustrates that the high-K gate dielectric layer 164 is not present between the gate spacer layer 130 and the gate coupling structure 178. Furthermore, the high-K gate dielectric layer 162 is not present between the gate spacer layer 130 and the wall structure 176.

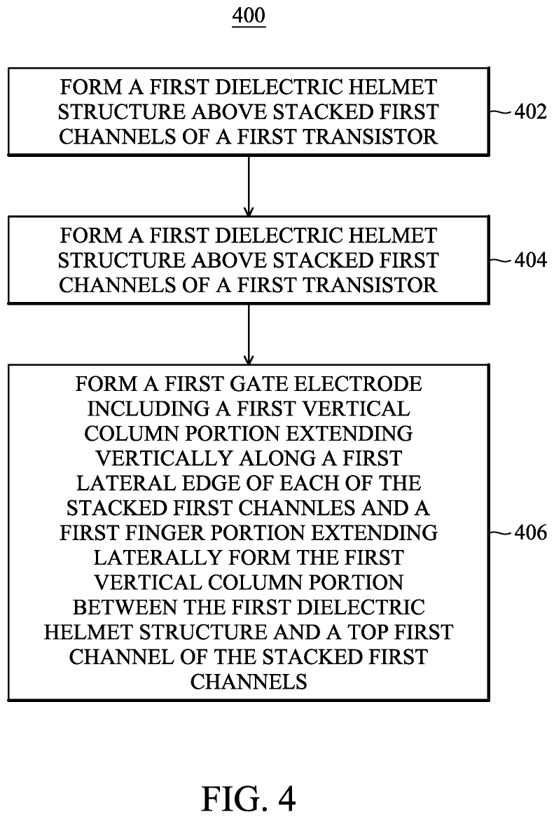

FIG. 4 is a flow diagram of a method 400 for forming an integrated circuit, in accordance with some embodiments. The method 400 can utilize structures, components, and processes described in relation to foregoing figures. At 402, the method 400 includes forming a first dielectric helmet structure above stacked first channels of a first transistor. One example of a first transistor is the first transistor 103b of FIG. 1V. One example of stacked first channels are the channels 106b of FIG. 1V. One example of a first dielectric helmet structure is the dielectric helmet structure 134b of FIG. 1V. At 404, the method 400 includes forming a first gate dielectric on the stacked first channels and on a bottom surface of the first dielectric helmet structure. One example of a first gate dielectric is the high-K gate dielectric layer 164 of FIG. 1V. At 406, the method 400 includes forming a first gate electrode including a first vertical column portion extending vertically along a first lateral edge of each of the stacked first channels and a first finger portion extending laterally from the first vertical column portion between the between the first dielectric helmet structure and a top first channel of the stacked first channels. One example of a first gate electrode is the gate electrode 175b of FIG. 1V. One example of a first vertical column portion is the first vertical column portion 171 of FIG. 1V. One example of a first finger portion is the first finger portions 173 of FIG. 1V.

Embodiments of the disclosure provide nanostructure transistors with reduced gate to source/drain capacitance. Embodiments of the present disclosure provide dielectric structures between adjacent channel stacks of adjacent transistors. The gate metals that are initially positioned between adjacent channel stacks is entirely replaced with dielectric material. This reduces the effect of area of gate metal that faces source/drain contact metals and source/drain regions. Furthermore, in some embodiments, a dielectric helmet structure may be placed directly above channel stacks to further reduce the height of the gate electrode and the area of gate metal that faces source/drain contact metals and source/drain regions. The result is that gate capacitances are greatly reduced. This further results in nanostructure transistors that can operate at higher frequencies, have superior electrical characteristics, and better overall performance. Furthermore, this can improve wafer yields and overall function of integrated circuits and electronic devices in which the integrated circuits are embedded.

In one embodiment, an integrated circuit includes a first transistor. The first transistor includes a plurality of stacked first channels, a first gate dielectric surrounding each of the first channels, and a first gate electrode. The first gate electrode includes a first vertical column portion extending vertically along a first lateral side of each of the first channels, and a plurality of first horizontal finger portions each protruding laterally from the first vertical column portion between adjacent first channels. The integrated circuit includes a first dielectric wall structure on second lateral side of the first channels opposite the first lateral side of the first channels and a second dielectric wall structure extending along a side of the vertical column portion opposite the first channels.

In one embodiment, a method includes forming a first dielectric helmet structure above stacked first channels of a first transistor and forming a first gate dielectric on the stacked first channels and on a bottom surface of the first dielectric helmet structure. The method includes forming a first gate electrode including a first vertical column portion extending vertically along a first lateral edge of each of the stacked first channels and a first finger portion extending laterally from the first vertical column portion between the between the first dielectric helmet structure and a top first channel of the stacked first channels.

In one embodiment, an integrated circuit includes a transistor. The transistor includes a plurality of stacked channels, a dielectric helmet structure positioned above the stacked channels, and a gate dielectric on the stacked channels and on a bottom surface of the dielectric helmet structure. The transistor includes a first gate metal in contact with the gate dielectric on the top surface of a top channel of the stacked channels and on the bottom surface of the dielectric helmet structure. The transistor includes a second gate metal in contact with the first gate metal between the top surface of the top channel and the bottom surface of the dielectric helmet structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit, comprising:
a first transistor including:
a plurality of stacked first channels;
a first gate dielectric surrounding each of the first channels;
a first gate electrode including:
a first vertical column portion extending vertically along a first lateral side of each of the first channels; and
a plurality of first horizontal finger portions each protruding laterally from the first vertical column portion between adjacent first channels;
a first dielectric wall structure on second lateral side of the first channels opposite the first lateral side of the first channels; and
a second dielectric wall structure extending along a side of the vertical column portion opposite the first channels.

2. The integrated circuit of claim 1, further comprising a dielectric helmet structure above a top first channel, wherein a top first finger portion extends between the dielectric helmet structure and the top first channel.

3. The integrated circuit of claim 2, wherein the gate dielectric is on a bottom surface of the dielectric helmet structure between the top first finger portion and the dielectric helmet structure.

4. The integrated circuit of claim 1, further comprising:
a second transistor including:
a plurality of stacked second channels;
a second gate dielectric surrounding each of the second channels;
a second gate electrode including:
a second vertical column portion extending vertically along a first lateral side of each of the first channels; and
a plurality of second horizontal finger portions each protruding laterally from the second vertical column portion and filling a space between adjacent second channels, wherein the second dielectric wall structure extends along a side of the second vertical column portion opposite the second channels.

5. The integrated circuit of claim 4, further comprising a conductive gate coupling structure on top of the second gate dielectric wall structure and in contact with the first vertical column portion and the second vertical column portion.

6. The integrated circuit of claim 5, wherein the conductive gate coupling structure is in contact with the gate dielectric.

7. The integrated circuit of claim 6, further comprising a lower metal connector extending below the second dielectric wall structure and electrically coupling the first vertical column portion to the second vertical column portion.

8. The integrated circuit of claim 1, wherein the first column portion and the first finger portions are a same first metal.

9. The integrated circuit of claim 8, further comprising a second metal in contact with the first gate dielectric between the stacked first channels, wherein each first finger portion is positioned between vertically adjacent portions of the second metal.

10. The integrated circuit of claim 1, wherein the first finger portions are a first metal and the first vertical column portion is a second metal different than the first gate metal.

11. A method, comprising:
forming a first dielectric helmet structure above stacked first channels of a first transistor;
forming a first gate dielectric on the stacked first channels and on a bottom surface of the first dielectric helmet structure; and
forming a first gate electrode including a first vertical column portion extending vertically along a first lateral edge of each of the stacked first channels and a first finger portion extending laterally from the first vertical column portion between the between the first dielectric helmet structure and a top first channel of the stacked first channels.

12. The method of claim 11, further comprising forming a first dielectric wall structure extending along a second lateral side of each of the first stack channels.

13. The method of claim 12, further comprising:
forming a second dielectric helmet structure above stacked second channels of a second transistor;
forming a second gate dielectric on the stacked second channels and on a bottom surface of the second dielectric helmet structure; and
forming a second gate electrode including a second vertical column portion extending vertically along a first lateral edge of each of the stacked second channels and a second finger portion extending laterally from the second vertical column portion between the between the second dielectric helmet structure and a top second channel of the stacked second channels.

14. The method of claim 13, further comprising forming second dielectric wall structure between and in contact with the first vertical column portion and second vertical column portion.

15. The method of claim 14, further comprising forming a conductive gate coupling structure on top of the first wall structure and in contact with the first and second vertical column portions.

16. The method of claim 14, wherein a lower conductive structure extends below the second wall portion electrically coupling the first vertical column portion to the second vertical column portion.

17. The method of claim 11, wherein forming the first gate electrode includes:
forming a first gate metal on the gate dielectric; and
forming the first finger portion and the first column portion from a second gate metal by selectively depositing the second gate metal on the first gate metal with a selective growth process.

18. An integrated circuit, comprising:
a transistor including:
a plurality of stacked channels;
a dielectric helmet structure positioned above the stacked channels;
a gate dielectric on the stacked channels and on a bottom surface of the dielectric helmet structure;
a first gate metal in contact with the gate dielectric on the top surface of a top channel of the stacked channels and on the bottom surface of the dielectric helmet structure; and
a second gate metal in contact with the first gate metal between the top surface of the top channel and the bottom surface of the dielectric helmet structure.

19. The integrated circuit of claim 18, further comprising a wall structure adjacent to a first lateral side of each of the stacked channels, the gate dielectric being positioned on the dielectric wall structure between the dielectric wall structure and the first gate metal.

20. The integrated circuit of claim 19, further comprising a second dielectric wall structure on a second lateral side of each of the stacked channels, wherein the second gate metal extends vertically between the second dielectric wall structure and the second lateral side of each of the stacked channels.
